(19) United States
(12) Patent Application Publication
(10) Pub. No.: US 2013/0240038 A1
(43) Pub. Date: Sep. 19, 2013

(54) PHOTOVOLTAIC DEVICE AND MANUFACTURING METHOD THEREOF

(71) Applicant: SANYO ELECTRIC CO., LTD., Osaka (JP)

(72) Inventors: Mitsuoki HISHIDA, Kaizu-shi (JP); Hiroyuki UENO, Osaka (JP)

(73) Assignee: SANYO Electric Co., Ltd., Osaka (JP)

(21) Appl. No.: 13/893,438

(22) Filed: May 14, 2013

Related U.S. Application Data
(63) Continuation of application No. PCT/JP2012/077313, filed on Oct. 23, 2012.

(30) Foreign Application Priority Data
Oct. 31, 2011 (JP) 2011-239077

(51) Int. Cl. H01L 31/0368; H01L 31/18

(52) U.S. Cl. CPC H01L 31/03685; H01L 31/1824
USPC 136/261; 438/97

(57) ABSTRACT

A photovoltaic device comprises a microcrystalline silicon layer, wherein the microcrystalline silicon layer, when a maximum value of a crystallinity Xc along a film thickness direction is scaled to 1, shows increasing tendency of the crystallinity Xc along the film thickness direction, and has a high-nitrogen-concentration region (region a) of higher nitrogen concentration than other regions in the microcrystalline silicon layer in a range of the film thickness direction where the crystallinity Xc is 0.75 or more.

### CROSS-REFERENCE TO RELATED APPLICATION

The present application is a continuation application of International Application No. PCT/JP2012/077313, filed Oct. 23, 2012, the entire contents of which are incorporated herein by reference and priority to which is hereby claimed. The PCT/JP2012/077313 application claimed the benefit of the date of the earlier filed Japanese Patent Application No. 2011-239077 filed Oct. 31, 2011, the entire content of which is incorporated herein by reference, and priority to which is hereby claimed.

### TECHNICAL FIELD

The present invention generally relates to a photovoltaic device and a manufacturing method thereof.

### BACKGROUND ART

As a power generation system using solar light, a photovoltaic device has been used in which a microcrystalline silicon layer is laminated as a power generating layer. The microcrystalline silicon layer includes a microcrystalline phase having a crystalline phase formed in amorphous silicon, has photostability higher than the amorphous silicon layer, and has a light absorption wavelength band different from the amorphous silicon layer. These characteristics are used in application to a tandem-type photovoltaic device having the layer and the amorphous silicon layer laminated therewith, for example.

However, when the microcrystalline silicon layer is used as the power generating layer, power generation efficiency thereof is greatly influenced by crystallinity of the microcrystalline silicon layer. For this reason, a method has been disclosed for improving a film quality by varying a hydrogen content rate in a film thickness direction when forming the microcrystalline silicon layer (e.g., Patent Literature 1).

### SUMMARY OF INVENTION

### Technical Problem

Here, it is desired to further enhance the power generation efficiency in the photovoltaic device which uses the microcrystalline silicon layer as the power generating layer. Therefore, technology for further enhancing the crystallinity of the microcrystalline silicon layer is required.

### Solution to Problem

According to an aspect of the invention, there is provided a photovoltaic device, including a microcrystalline silicon layer, wherein the microcrystalline silicon layer, when a maximum value of a crystallinity Xc along a film thickness direction is scaled to 1, shows increasing tendency of the crystallinity Xc along the film thickness direction, and has a high-nitrogen-concentration region of higher nitrogen concentration than other regions in the microcrystalline silicon layer in a range of the film thickness direction where the crystallinity Xc is 0.75 or more.

According to another aspect of the invention, there is provided a method for manufacturing a photovoltaic device, including the step of converting a film formation gas including silicon into plasma to form a microcrystalline silicon layer, in which when a maximum value of a crystallinity Xc along a film thickness direction is scaled to 1, supply of the film formation gas is stopped in a range of the film thickness direction where the crystallinity Xc is 0.75 or more, the crystallinity Xc having increasing tendency along the film thickness direction.

### BRIEF DESCRIPTION OF DRAWINGS

FIG. 1 is a cross-sectional view showing a structure of a photovoltaic device according to an embodiment of the invention.

FIG. 2 shows a result of measuring a microcrystalline silicon layer by SIMS according to the embodiment of the invention.

FIG. 3 shows a result of measuring the microcrystalline silicon layer by Raman spectrometry according to the embodiment of the invention.

### DESCRIPTION OF EMBODIMENTS

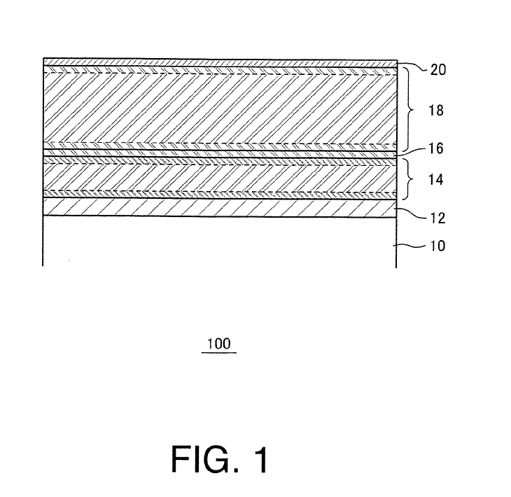

A solar cell 100 according to an embodiment of the invention is configured to include a substrate 10, a transparent electrode layer 12, a first photoelectric conversion unit 14, an interlayer 16, a second photoelectric conversion unit 18 and a back electrode layer 20 as shown in a cross-sectional view of FIG. 1.

The transparent electrode layer 12 is formed on the substrate 10. The substrate 10 is made of translucent material. The substrate 10 may be, for example, a glass substrate, a plastic substrate or the like. The transparent electrode layer 12 is a transparent conductive film. The transparent electrode layer 12 may be formed using at least one or any combination of transparent conductive oxides (TCOs) which are obtained by doping tin oxide (SnO₂), zinc oxide (ZnO), indium tin oxide (ITO) and the like with tin (Sn), antimony (Sb), fluorine (F), aluminum (Al) and/or the like. The transparent electrode layer 12 may be formed by, for example, a sputtering method or an MOCVD method (thermal CVD). One or both of the substrate 10 and the transparent electrode layer 12 may be preferably provided with irregularities (texture structure) on an interface therebetween.

In a case of an arrangement in which a plurality of photoelectric conversion cells are connected in series, the transparent electrode layer 12 may be provided with a first slit formed therein to be patterned into a rectangle. The slit can be formed by laser machining. For example, the transparent electrode layer 12 can be patterned into a rectangle using a YAG laser of 1064 nm wavelength.

The first photoelectric conversion unit 14 is formed on the transparent electrode layer 12. In the embodiment, the first photoelectric conversion unit 14 is a non-crystalline (amorphous) silicon solar cell (a-Si unit).

The first photoelectric conversion unit 14 is formed by laminating p-type, i-type and n-type amorphous silicon films in this order from the substrate 10 side. The first photoelectric conversion unit 14 can be formed by, for example, a plasma chemical vapor deposition (CVD) method. As for the plasma CVD method, for example, an RF plasma CVD method of 13.56 MHz may be preferably applied. At this time, the p-type, i-type and n-type amorphous silicon films can be formed by converting a mixture gas into plasma to form a film, the mixture gas being obtained by mixing a silicon-containing gas such as silane (SiH₄), disilane (Si₂H₆) or dichlorosilane (SiH₇Cl₂), a carbon-containing gas such as methane (CH₄), a p-type dopant-containing gas such as diborane (B₂H₆), an n-type dopant-containing gas such as phosphine (PH₃), and a dilution gas such as hydrogen (H₂). An i-layer of the first photoelectric conversion unit 14 preferably has a film thickness of 100 nm or more and 500 nm or less.

In the embodiment, the i-type means an intrinsic semiconductor layer, that is, a semiconductor layer in which dopant concentrations of n-type and p-type are 5×10¹⁹/cm³ or less even if the n-type and p-type dopant concentrations are included. Further, the p-type semiconductor layer means a semiconductor which is doped with a p-type dopant such as boron (B) and has the p-type dopant concentration of 5×10²°/cm³ or more and 1×10²²/cm³ or less. The n-type semiconductor layer means a semiconductor which is doped with an n-type dopant such as phosphorus (P) and has the n-type dopant concentration of 5×10²⁰/cm³ or more and 1×10²²/cm³ or less.

For example, the first photoelectric conversion unit 14 may be formed under film formation conditions shown in TABLE 1.

TABLE 1

| | | Substrate | Gas flow | Reaction | RF | Film |
|---|---|---|---|---|---|---|
| | | temperature | rate | pressure | power | thickness |
| | Layer | (° C.) | (sccm) | (Pa) | (W) | (nm) |
| a-Si | p- | 180 | SiH₄: 300 | 106 | 10 | 15 |
| unit | type | | CH₄: 300 | | | |
| 14 | layer | | H₂: 2000 | | | |
| | | | B₂H₆: 3 | | | |
| | i-type | 180 | SiH₄: 300 | 106 | 20 | 250 |
| | layer | | H₂: 2000 | | | |
| | n- | 180 | SiH₄: 300 | 133 | 20 | 30 |
| | type | | H₂: 2000 | | | |
| | layer | | PH₃: 5 | | | |

The interlayer 16 is formed on the first photoelectric conversion unit 14. In the embodiment, the interlayer 16 may be preferably the transparent conductive oxide (TCO) such as oxide silicon (SiOx). Particularly, oxide silicon (SiOx) doped with magnesium (Mg) or phosphine (P) is preferably used. The transparent conductive oxide (TCO) can be made by the plasma CVD method or a DC sputtering method. The interlayer 16 preferably has a film thickness of 50 nm or more and 200 nm or less. Note that the interlayer 16 may not be provided.

The second photoelectric conversion unit 18 is formed on the interlayer 16. In the embodiment, the second photoelectric conversion unit 18 is a microcrystalline silicon solar cell (μc-Si unit).

The second photoelectric conversion unit 18 is formed by laminating the p-type, i-type and n-type microcrystalline silicon films in this order from the substrate 10 side. The second photoelectric conversion unit 18 can be the plasma CVD method. For the plasma CVD method, for example, the RF plasma CVD method of 13.56 MHz may be preferably applied. The second photoelectric conversion unit 18 can be formed by converting the mixture gas into plasma to form a film, the mixture gas being obtained by mixing the silicon-containing gas such as silane (SiH₄), disilane (Si₇H₆) or dichlorosilane (SiH₂Cl₂), the carbon-containing gas such as methane (CH₄), the p-type dopant-containing gas such as diborane (B₂H₆), the n-type dopant-containing gas such as phosphine (PH₃), and the dilution gas such as hydrogen. An i-layer of the second photoelectric conversion unit 18 preferably has a film thickness of 1000 nm or more and 5000 nm or less.

For example, the second photoelectric conversion unit 18 may be formed under film formation conditions shown in TABLE 2.

TABLE 2

| | | Substrate | Gas flow | Reaction | RF | Film |
|---|---|---|---|---|---|---|
| | | temperature | rate | pressure | power | thickness |
| | Layer | (° C.) | (sccm) | (Pa) | (W) | (nm) |
| μc-Si | p- | 180 | SiH₄: 10 | 106 | 10 | 30 |
| unit | type | | H₂: 2000 | | | |
| 18 | layer | | B₂H₆: 3 | | | |
| | i- | 180 | SiH₄: | 133 | 20 | 2000 |
| | type | | 100 | | | |
| | layer | | H₂: 2000 | | | |
| | n- | 180 | SiH₄: 10 | 133 | 20 | 20 |
| | type | | H₂: 2000 | | | |
| | layer | | PH₃: 5 | | | |

In the embodiment, a high-nitrogen-concentration region is provided in the microcrystalline silicon layer when forming the i-type layer. During the film formation, electrical power for generating the plasma is stopped and a gas for film formation is stopped to evacuate the device into a vacuum such that residual nitrogen in a film formation device is taken in the microcrystalline silicon layer. This allows the high-nitrogen-concentration region to be provided which has higher nitrogen concentration than other regions in the microcrystalline silicon layer.

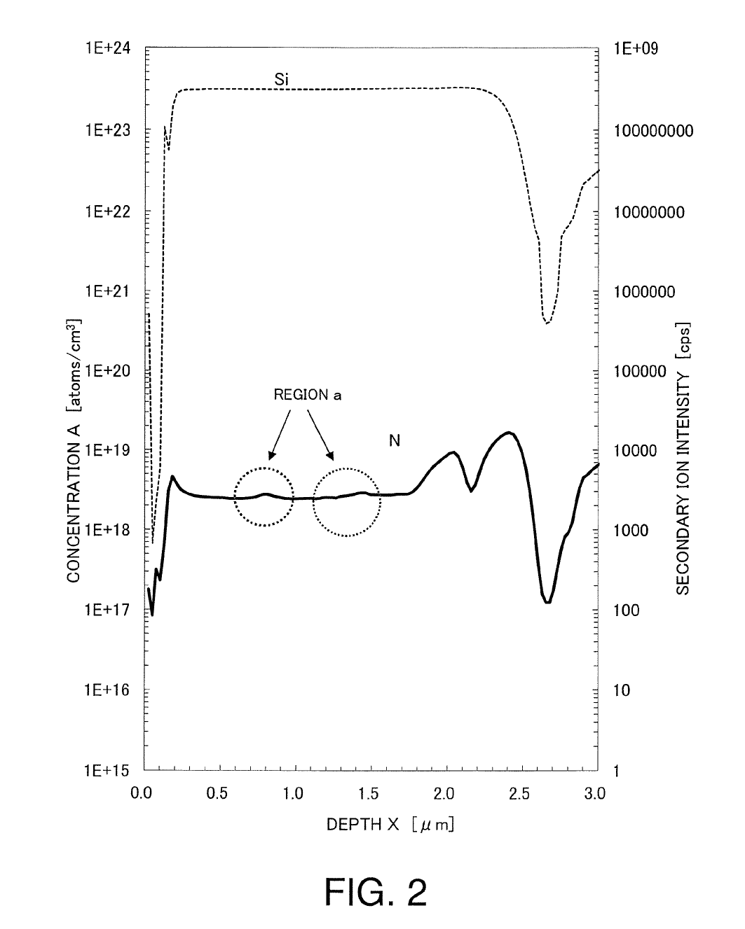

The nitrogen concentration in the microcrystalline silicon layer may be measured by secondary ion mass spectrometry (SIMS). FIG. 2 shows a result of carrying out the SIMS measurement on a single film of the microcrystalline silicon layer formed on the substrate 10. In FIG. 2, the abscissa represents a depth X of the microcrystalline silicon layer in a film thickness direction, and the ordinate represents a concentration A and a secondary ion intensity of silicon (²⁸Si: dashed line) and nitrogen (N: solid line) in the SIMS measurement.

The high-nitrogen-concentration region is detected as a peak, like a region a in FIG. 2, in which the nitrogen (N) concentration is increased in comparison to the other region. In the embodiment, the high-nitrogen-concentration region is defined as a region in which, with respect to a nitrogen (N) concentration A_{N1} at a depth X₁ of the microcrystalline silicon layer, a concentration A_{N2} at a depth X₂ (=X₁+50 nm) apart from the depth X₁ by 50 nm is varied by 3% or more. That is, the high-nitrogen-concentration region is a region which satisfies the following formula (1).

### (Formula 1)

(A_{N2}−A_{N1})/A_{N1}≧0.03(=3%) (1)

In the embodiment, assuming a peak value (maximum value) of a crystallinity of the microcrystalline silicon layer is scaled to 1, the high-nitrogen-concentration region is provided in a film thickness range where the crystallinity Xc is 0.75 or more.

The crystallinity Xc can be measured by Raman spectrometry. In the Raman spectrometry, the peak due to monocrystalline silicon is observed around 520 cm⁻¹, and the peak due to amorphous silicon is observed around 480 cm⁻¹. In the microcrystalline silicon layer, a silicon crystal is pulverized into microparticulates, and a peak position around 520 cm⁻¹ is shifted to a low wavenumber side to widen a half-value width of the peak.

In the embodiment, a crystalline oxide silicon film of from 100 to 300 nm is formed on the glass substrate, and respective regions on a surface of the crystalline oxide silicon film are irradiated with light of 514 nm wavelength to detect a Raman scattering spectrum. Subsequently, using the obtained data, a straight line connecting an intensity at 400 cm⁻¹ and an intensity at 600 cm⁻¹ is drawn and this line is set as a baseline for eliminating noise. Then, a maximum intensity Ic which appears around 520 cm⁻¹ and a maximum intensity Ia which appears around 480 cm⁻¹, both intensities appearing after subtracting a value of the baseline from the measured spectrum, are used, and Formula (2) is applied to calculate a value, which is set as a crystallinity Xc.

### (Formula 2)

Crystallinity Xc=Ic/Ia (2)

The film thickness where the crystallinity Xc is 0.75 or more can be grasped in advance by, under film formation conditions the same as the actual film formation conditions, forming a single film of the microcrystalline silicon layer on the substrate 10 and performing the Raman spectrometry on the microcrystalline silicon layers of various film thicknesses. Then, depending on a relationship between a film formation time and the film thickness of the microcrystalline silicon layer, when the film formation time corresponding to the film thickness where the crystallinity Xc becomes 0.75 or more has elapsed, a high-nitrogen-concentration region is introduced.

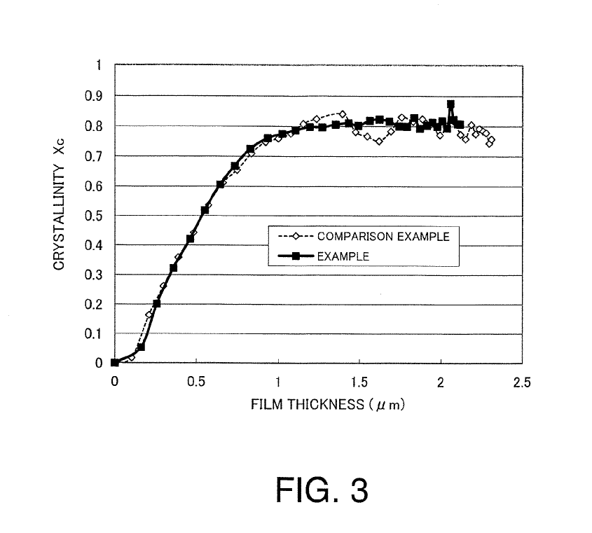

FIG. 3 shows variation of the crystallinity Xc, with respect to the film thickness direction, of the microcrystalline silicon layer not introduced with the high-nitrogen-concentration region (Comparison example) and the microcrystalline silicon layer introduced with the high-nitrogen-concentration region when the layer has the film thickness where the crystallinity Xc is 0.75 or more (Example). The crystallinity Xc of the Comparison example increases as the film thickness increases, but drops steeply after passing the peak value around the film thickness of 1.3 μm and thereafter increases again. On the other hand, the crystallinity Xc of the Example increases as the film thickness increases, and keeps the high crystallinity without dropping steeply after passing the peak value.

In this way, the introduction of the high-nitrogen-concentration region at the film thickness where the crystallinity Xc is 0.75 or more can prevent a region in the film thickness direction from being generated where the crystallinity Xc of the microcrystalline silicon layer drops. This allows the power generation efficiency in the second photoelectric conversion unit 18 to be enhanced.

In the case of the arrangement where the plurality of photoelectric conversion cells are connected in series, a second slit is formed to be patterned into a rectangle. The second slit is formed so as to penetrate the second photoelectric conversion unit 18, the interlayer 16 and the first photoelectric conversion unit 14 to reach the transparent electrode layer 12. The second slit may be formed by, for example, laser machining. The laser machining preferably is performed using a wavelength of about 532 nm (second harmonic of the YAG laser), but is not limited thereto.

The back electrode layer 20 is formed on the second photoelectric conversion unit 18. The back electrode layer 20 is preferably formed by combination of the transparent conductive oxide (TCO) with a metal layer. The transparent conductive oxides such as tin oxide (SnO₂), zinc oxide (ZnO) and indium tin oxide (ITO), or those doped with impurities are used. For example, the oxide obtained by doping zinc oxide (ZnO) with aluminum (Al) as impurity may be used. The transparent conductive oxide is formed by, for example, the sputtering method or the MOCVD method (thermal CVD). The metal layer is a metal layer including metal such as silver (Ag), copper (Cu), aluminum (Al), or the like. Particularly, silver (Ag) may be preferably used in terms of high reflectance and conductivity. The metal layer may be formed by the sputtering method or the like. Additionally, the metal layer may have a structure where titanium (Ti) or the like is laminated in order to prevent oxidation of silver or the like.

In the case of the arrangement where the plurality of photoelectric conversion cells are connected in series, the back electrode layer 22 is embedded in the second slit, and the back electrode layer 20 and the transparent electrode layer 12 are electrically connected in the second slit. Further, a third slit is formed in the back electrode layer 20 to be patterned in to a rectangle. The third slit is formed so as to penetrate the back electrode layer 20, the second photoelectric conversion unit 18, the interlayer 16 and the first photoelectric conversion unit 14 to reach the transparent electrode layer 12. The third slit is formed at a position to sandwich the second slit between the first and third slits. The third slit may be formed by laser machining. For example, the third slit is formed by irradiating a YAG laser at a position laterally displaced 50 μm from a second slit position. Further, a groove may be provided by the laser machining for splitting a periphery of the solar cell 100 into a peripheral area and a power generation area.

A back surface of the photovoltaic device 100 may be sealed by sealing material. Sealing is performed using the sealing material via a packed layer which is made of resin such as ethylene vinyl acetate (EVA), polyvinyl butyral (PVB) or the like. The sealing material is preferably a material that stable mechanically and chemically, such as the glass substrate or a plastic sheet. This can prevent moisture from entering a power generating layer of the photovoltaic device 100.

As described above, in the embodiment, the crystallinity Xc of the microcrystalline silicon layer of the second photoelectric conversion unit 18 can be improved, enhancing the power generation efficiency of the photovoltaic device 100.

1. A photovoltaic device, comprising:
a microcrystalline silicon layer, wherein
the microcrystalline silicon layer, when a maximum value of a crystallinity Xc along a film thickness direction is scaled to 1, shows increasing tendency of the crystallinity Xc along the film thickness direction, and has a high-nitrogen-concentration region of higher nitrogen concentration than other regions in the microcrystalline silicon layer in a range of the film thickness direction where the crystallinity Xc is 0.75 or more.

2. The photovoltaic device according to claim 1, wherein the high-nitrogen-concentration region is a region in which, with respect to a nitrogen (N) concentration A_{N1} at a depth X₁ of the microcrystalline silicon layer, a concentration A_{N2} at a depth X₂ (=X₁+50 nm) apart from the depth X₁ by 50 nm is varied by 3% or more.

3. A method for manufacturing a photovoltaic device, comprising the step of:
converting a film formation gas including silicon into plasma to form a microcrystalline silicon layer, in which when a maximum value of a crystallinity Xc along a film thickness direction is scaled to 1, supply of the film formation gas is stopped in a range of the film thickness direction where the crystallinity Xc is 0.75 or more, the crystallinity Xc having increasing tendency along the film thickness direction.
